(19) United States
(12) Patent Application Publication
(10) Pub. No.: US 2025/0337398 A1
(43) Pub. Date: Oct. 30, 2025

(54) LEVEL SHIFTING CIRCUIT AND LEVEL SHIFTING CIRCUIT AND LEVEL SHIFTING METHOD BASED ON LOW POWER SOURCE

(71) Applicant: SUZHOU MI TU OPTOELECTRONIC TECHNOLOGY CO. LTD., Suzhou (CN)

(72) Inventors: Zhi ZHANG, Suzhou (CN); Rongzhao TANG, Suzhou (CN); Haiming ZHUANG, Suzhou (CN); Yuqing MA, Suzhou (CN); Yunzhao LI, Suzhou (CN); Xianglin XIANG, Suzhou (CN)

(21) Appl. No.: 18/764,291

(22) Filed: Jul. 4, 2024

(30) Foreign Application Priority Data
Apr. 29, 2024 (CN) 202410528084.X

(51) Int. Cl. H03K 3/356; H03K 19/0185

(52) U.S. Cl. CPC H03K 3/356113; H03K 19/018521

(57) ABSTRACT

The present application provides a level shifting circuit and level shifting method based on low power source, belonging to the field of circuit design. The level shifting circuit comprising low power source, inverter and voltage conversion circuit. The low power source is connected to the power terminal of the inverter. A boosting capacitor circuit is provided between the inverter and the voltage conversion circuit. The boosting capacitor circuit controls the current flow from the low power source to the voltage conversion circuit, and generates a converted high voltage that is twice the voltage value of the low power source. It outputs the converted high voltage through the voltage conversion circuit. This solution uses only a low power source without the need for a high power source and utilizes the boosting capacitor circuit to generate a converted high voltage that is twice the voltage value of the low power source. This realizes level shifting from low voltage to high voltage, omits the high voltage source, and simplifies the circuit design.

### TECHNICAL FIELD

The present invention belongs to the field of circuit design, specifically focusing on a level shifting circuit and method based on a low power source.

### BACKGROUND

In analog circuits, digital-analog hybrid circuits, or PCB board-level circuits, level shifting circuits are often employed. The conventional structure of a level-shifting circuit is depicted in FIG. 1. It typically comprises two power sources (the low power source VCCL_supply and the high power source VCCH_supply), a low power source inverter (composed of Mp1, Mn1), and six field-effect transistors (consisting of Mnls1, Mpls1, Mpls2, Mnrs1, Mprs1, Mprs), facilitating level shifting from low voltage to high voltage.

Since the existing level shifting circuit uses both the low power source VCCL_supply and the high power source VCCH_supply, the difficulty and complexity of circuit design are increased.

### SUMMARY

Starting from another technical perspective, the present invention provides a brand-new level shifting circuit and level shifting method based on a low power source, without the need for a high power source, it uses only a low power source to convert a low-voltage control signal into a high-voltage control signal.

To achieve the above purpose, the technical solutions of the present application are as follows:
In one aspect, the present invention provides a level shifting circuit based on a low power source, comprising low power source, inverter and voltage conversion circuit, the low power source is connected to the power terminal of the inverter;
a boosting capacitor circuit is provided between the inverter and the voltage conversion circuit, the boosting capacitor circuit controls the current flow from the low power source to the voltage conversion circuit, and generates a converted high voltage that is twice the voltage value of the low power source, and outputs the converted high voltage through the voltage conversion circuit.

In the above level shifting circuit, the boosting capacitor circuit comprises a first unidirectional conducting tube, a second unidirectional conducting tube and a boosting capacitor, the first unidirectional conducting tube and the second unidirectional conducting tube are connected to control current flow from the low power source to the voltage conversion circuit, the lower plate of the boosting capacitor is connected to the output end of the inverter, and the upper plate of the boosting capacitor is connected to the connection ends of the first unidirectional conducting tube and the second unidirectional conducting tube, and a converted high voltage that is twice the voltage value of the low power source is generated at the connection end.

Optionally, in the above level shifting circuit, the first unidirectional conducting tube and the second unidirectional conducting tube are PMOS transistors, the source of the first unidirectional conducting tube is connected to the low power source, the gate and drain of the first unidirectional conducting tube are connected and connected to the upper plate of the boosting capacitor, the source of the second unidirectional conducting tube is connected to the drain of the first unidirectional conducting tube, the gate and drain of the second unidirectional conducting tube are connected to one end of the voltage conversion circuit.

Optionally, in the above level shifting circuit, the first unidirectional conducting tube and the second unidirectional conducting tube are NMOS transistors, the gate and drain of the first unidirectional conducting tube are connected and connected to the low power source, the source of the first unidirectional conducting tube is connected to the upper plate of the boosting capacitor, the gate of the second unidirectional conducting tube is connected to the drain and connected to the source of the first unidirectional conducting tube, the source of the second unidirectional conducting tube is connected to one end of the voltage conversion circuit.

Optionally, in the above level shifting circuit, the first unidirectional conducting tube is a diode, PMOS transistor or NMOS transistor, and the second unidirectional conducting tube is a diode, PMOS transistor or NMOS transistor.

In the above level shifting circuit, the boosting capacitor circuit further comprises a voltage holding capacitor, the upper plate of the voltage holding capacitor is connected to one end of the voltage conversion circuit, and the lower plate of the voltage holding capacitor is grounded.

Optionally, in the above level shifting circuit, the inverter includes a first inverter and a second inverter;
wherein the first inverter includes a first PMOS transistor and a first NMOS transistor, the gate of the first PMOS transistor and the gate of the first NMOS transistor are connected as the input terminal of the first inverter and connected to the input voltage, the drain of the first PMOS transistor and the drain of the first NMOS transistor are connected as the output terminal of the first inverter, the output terminal of the first inverter is connected to the input terminal of the second inverter, the source of the first PMOS transistor is connected to the low power source, the source of the first NMOS transistor is grounded;
wherein the second inverter includes a second PMOS transistor and a second NMOS transistor, the gate of the second PMOS transistor and the gate of the second NMOS transistor are connected as the input terminal of the second inverter, the drain of the second PMOS transistor and the drain of the second NMOS transistor are connected as the output terminal of the second inverter, the output end of the second inverter is connected to the lower plate of the boosting capacitor, the source of the second PMOS transistor is connected to the low power source, the source of the second NMOS transistor is grounded.

Optionally, in the above level shifting circuit, the voltage conversion circuit comprises a third PMOS transistor, a fourth PMOS transistor, a fifth PMOS transistor, a sixth PMOS transistor, as well as a third NMOS transistor and a fourth NMOS transistor;
wherein the source of the third PMOS transistor is connected to the source of the fourth PMOS transistor and connected to the output end of the second unidirectional conductor, the drains of the third PMOS transistor and the fourth PMOS transistor are respectively connected to the sources of the fifth PMOS transistor and the sixth PMOS transistor, the drains of the fifth PMOS transistor and the sixth PMOS transistor are respectively connected to the drains of the third NMOS transistor and the fourth NMOS transistor, the sources of the third NMOS transistor and the fourth NMOS transistor are grounded;
wherein the gate of the fifth PMOS transistor is connected to the gate of the third NMOS transistor and connected to the input voltage, the gate of the sixth PMOS transistor is connected to the gate of the fourth NMOS transistor and connected to the inverse voltage of the input voltage;
wherein the gate of the fourth PMOS transistor is connected to the drain of the fifth PMOS transistor, the gate of the third PMOS transistor is connected to the drain of the sixth PMOS transistor and serves as the output voltage terminal of the voltage conversion circuit.

Optionally, in the above level shifting circuit, the body and source of the fifth PMOS transistor are connected, the body and source of the sixth PMOS transistor are connected.

Optionally, in the above level shifting circuit, the body of the fifth PMOS transistor is connected to the body of the sixth PMOS transistor and connected to the output end of the second unidirectional conducting tube.

In order to better achieve the purpose of the invention, another aspect of the present invention provides a level shifting method based on a low power source, comprising low power source, inverter and voltage conversion circuit, the low power source is connected to the power terminal of the inverter, the method comprising:
providing a boosting capacitor circuit between the inverter and the voltage conversion circuit, the boosting capacitor circuit comprises a first unidirectional pass tube, a second unidirectional pass tube and a boosting capacitor, the first unidirectional conducting tube and the second unidirectional conducting tube are connected, the lower plate of the boosting capacitor is connected to the output end of the inverter, and the upper plate of the boosting capacitor is connected to the connection ends of the first unidirectional conducting tube and the second unidirectional conducting tube;
controlling current flow from the low power source to the voltage conversion circuit through the first unidirectional conducting tube and the second unidirectional conducting tube;
generating a converted high voltage that is twice the voltage value of the low power source by the boosting capacitor circuit, and outputs the converted high voltage through the voltage conversion circuit.

The effects provided in the summary of the invention are only the effects of the embodiments, rather than all the effects of the invention, one of the above technical solutions has the following advantages or beneficial effects:

The level shifting circuit and level shifting method based on low power source provided by this application involve placing a boosting capacitor circuit is provided between the inverter and the voltage conversion circuit. The boosting capacitor circuit controls the current flow from the low power source to the voltage conversion circuit, generating a converted high voltage that is twice the voltage value of the low power source. This high voltage is then outputted through the voltage conversion circuit. This solution uses only a low power source without the need for a high power source, and uses the boosting capacitor circuit to generate a converted high voltage that is twice the voltage value of the low power source, thereby realizing level shifting from low voltage to high voltage, omitting the high voltage source, and simplifying the circuit design.

### BRIEF DESCRIPTION OF THE DRAWING

The accompanying drawings are incorporated into the description and form a part thereof, illustrating embodiments consistent with this application, and used together with the description to explain the principles of this application.

FIG. 1 is a schematic structural diagram of a level shifting circuit in the prior art;

FIG. 2 is a schematic structural diagram of a level shifting circuit based on a low power source according to this application;

FIG. 3 is a schematic structural diagram of a level shifting circuit based on a low power source according to one embodiment of this application;

FIG. 4 is a schematic structural diagram of a level shifting circuit based on a low power source according to another embodiment of this application;

FIG. 5 is a schematic diagram of the simulation results of the level shifting circuit based on a low power source as shown in FIG. 3;

FIG. 6 is a schematic structural diagram of a level shifting circuit based on a low power source according to another embodiment of this application;

FIG. 7 is a schematic structural diagram of a level shifting circuit based on a low power source according to another embodiment of this application;

FIG. 8 is a schematic structural diagram of a level shifting circuit based on a low power source according to another embodiment of this application;

FIG. 9 is a schematic flow chart of a level shifting circuit based on a low power source according to this application;

### REFERENCE SIGNS

210—Low power source, 220—Inverter, 230—Voltage conversion circuit, 240—Boosting capacitor circuit, 241—First unidirectional conducting tube, 242—Second unidirectional conducting tube, 243—Boosting capacitor.

### DETAILED DESCRIPTION

In order to make the objectives, technical solutions, and advantages of the present invention more clear, the invention will be further described in detail below in conjunction with the accompanying drawings and embodiments. It should be understood that the specific embodiments described herein are only intended to explain the present invention and are not meant to limit it.

It should be noted that references to “one embodiment”, “embodiment”, “exemplary embodiment”, etc. in this specification mean that the described embodiment may include a particular feature, structure or characteristic, but not every embodiment must include that particular feature, structure or characteristic. Moreover, such expressions do not necessarily refer to the same embodiment. Furthermore, when a particular feature, structure or characteristic is described in conjunction with an embodiment, whether or not explicitly described, it will be shown that it is within the knowledge of those skilled in the art to integrate such feature, structure or characteristic into other embodiments.

Furthermore, in the specification and subsequent claims, certain terms are used to refer to specific components or parts, which would be understood by one skilled in the art to include various alternative names or terminologies for the same component or part. The specification and subsequent claims do not distinguish components or parts based on differences in nomenclature, but rather based on differences in functionality. The terms “comprising” and “including” used throughout the specification and subsequent claims are to be interpreted in an open-ended manner, meaning “including but not limited to”. Additionally, the term “connection” herein encompasses any direct or indirect electrical connection means. Indirect electrical connection means include connections made through other devices.

As described in the background technology, existing level shifting circuits typically require both a low power source and a high power source to achieve level shifting from low voltage to high voltage, which increases the complexity of circuit design. Based on this, the core of the present application is to provide a level shifting circuit with a different concept from the existing technology, without the need for a high power source, the circuit uses only a low power source generates high voltage through a boosting capacitor circuit to achieve level shifting from low voltage to high voltage. In practical applications, the high voltage generated by the boosting capacitor circuit is twice the voltage value of the low power source, its technical effect can reach the level of existing level shifting circuits, and since the high power source is omitted, the circuit design is simplified.

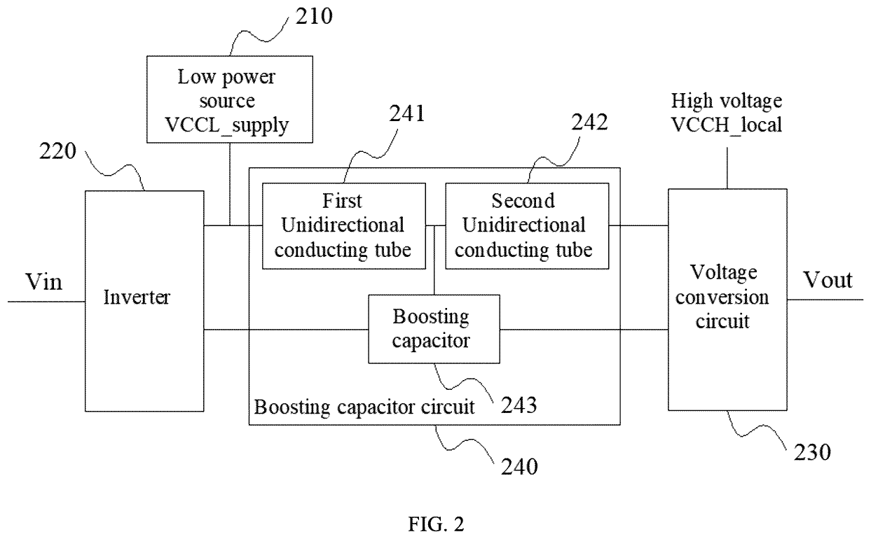

Referring to FIG. 2, which illustrates the schematic structural diagram of the level shifting circuit structure based on a low power source according to this application. As can be seen from the figure, the level shifting circuit of this application includes a low power source 210, an inverter 220, and a voltage conversion circuit 230, wherein the low power source 210 is connected to the power terminal of the inverter 220, a boosting capacitor 240 circuit is provided between the inverter 220 and the voltage conversion circuit 230, the boosting capacitor circuit 240 is used to control the current flow from the low power source 210 to the voltage conversion circuit 230, and generate a converted high voltage that is twice the voltage value of the low power source, and then output the converted high voltage through the voltage conversion circuit 230.

Continue to refer to FIG. 2, in one embodiment, the boosting capacitor circuit 240 comprises a first unidirectional conducting tube 241, a second unidirectional conducting tube 242, and a boosting capacitor 243, wherein the first unidirectional conducting tube 241 and the second unidirectional conducting tube 242 are connected to control current flow from the low power source 210 to the voltage conversion circuit 230, one end of the boosting capacitor 243 is connected to the output end of the inverter 220, and the other end is connected to the connection ends of the first unidirectional conducting tube 241 and the second unidirectional conducting tube 242, and a converted high voltage that is twice the voltage value of the low power source is generated at the connection end, then the converted high voltage is output through the voltage conversion circuit 230.

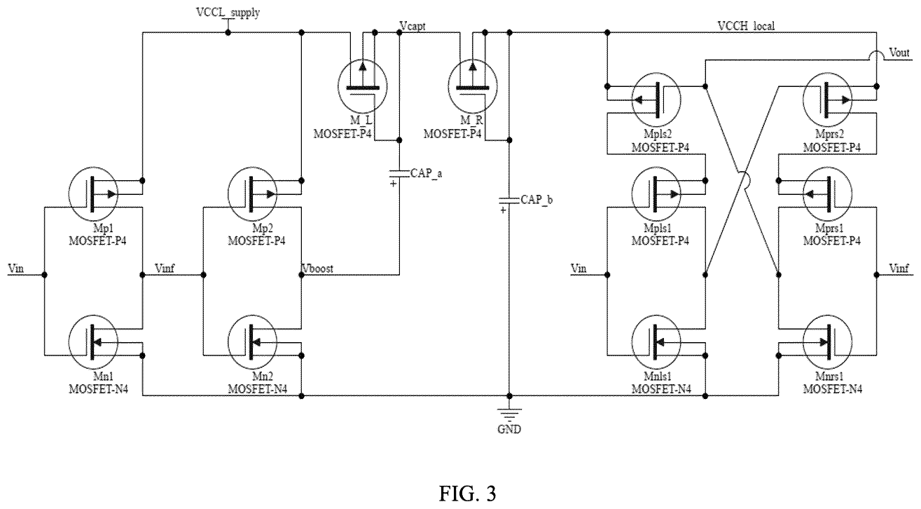

The level shifting circuit of the present application will be described in detail below in conjunction with specific circuit structures. Referring to FIG. 3, FIG. 3 shows a schematic structural diagram of a level shifting circuit based on a low power source according to an embodiment of the present application, in this embodiment, the boosting capacitor 243 uses capacitor CAP_a, the lower plate of capacitor CAP_a is connected to the output end of the inverter 220, and the upper plate of capacitor CAP_a is connected to the connection end Vcapt of the first unidirectional conducting tube 241 and the second unidirectional conducting tube 242.

Additionally, as a preferred option, the boosting capacitor circuit 240 may further include a voltage holding capacitor CAP_b, the upper plate of capacitor CAP_b is connected to one end of the voltage conversion circuit VCCH_local, and the lower plate of capacitor CAP_b is grounded, assisting in maintaining the voltage on the upper plate of capacitor CAP_a.

As shown in FIG. 3, in this embodiment, the first unidirectional conducting tube 241 is implemented as a PMOS transistor M_L, and the second unidirectional conducting tube 242 is implemented as a PMOS transistor M_R, the source of the first unidirectional conducting tube M_L is connected to the low power source VCCL_supply, the gate and drain of the first unidirectional conducting tube M_L are connected together and are also connected to the upper plate of capacitor CAP_a, the source of the second unidirectional conducting tube M_R is connected to the drain of the first unidirectional conducting tube M_L, the gate and drain of the second unidirectional conducting tube M_R are connected together and are also connected to one end of the voltage conversion circuit VCCH_local.

In a specific implementation, the inverter 210 may include one inverter, or it may include two or more inverters, and the present application is not limited to any specific number. This embodiment uses two inverters as an example for illustration, the inverter 210 includes a first inverter and a second inverter, the input of the first inverter is Vin, and the output of the second inverter is Vboost, therefore, Vin and Vboost are in phase, wherein:
the first inverter includes a first PMOS transistor Mp1 and a first NMOS transistor Mn1, the gate of Mp1 and the gate of Mn1 are connected together to serve as the input of the first inverter, the drain of Mp1 and the drain of Mn1 are connected together to serve as the output of the first inverter, the output of the first inverter is connected to the input of the second inverter, the source of Mp1 is connected to the low power source, and the source of Mn1 is grounded;
the second inverter includes a second PMOS transistor Mp2 and a second NMOS transistor Mn2, the gate of Mp2 and the gate of Mn2 are connected together to serve as the input of the second inverter, the drain of Mp2 and the drain of Mn2 are connected together to serve as the output of the second inverter, the output of the second inverter is connected to the upper plate of capacitor CAP_a, the source of Mp2 is connected to the low power source, and the source of Mn2 is grounded.

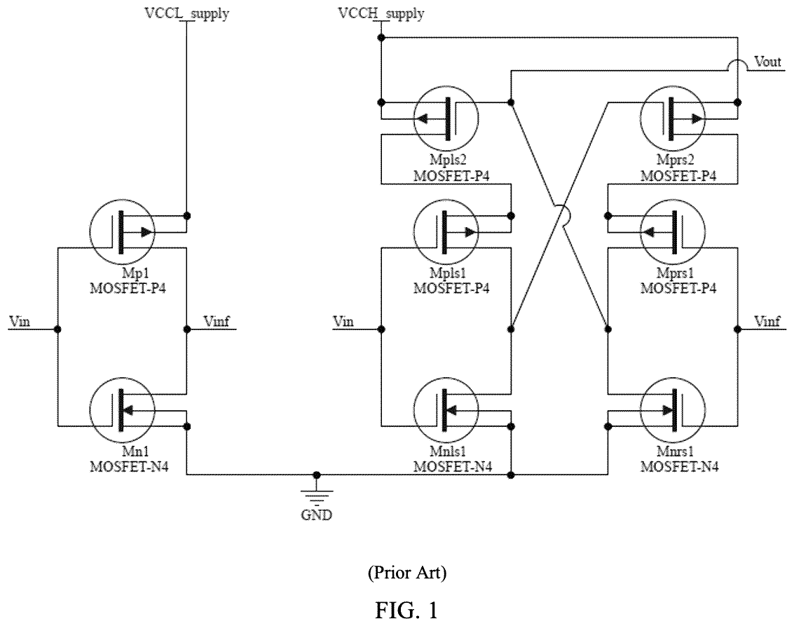

Of course, in other embodiments, the inverter 210 may include only the first inverter, the first inverter comprises a first PMOS transistor Mp1 and a first NMOS transistor Mn1, the gate of Mp1 and the gate of Mn1 are connected together to serve as the input of the first inverter, the drain of Mp1 and the drain of Mn1 are connected together to serve as the output of the first inverter, the output of the first inverter is connected to the upper plate of capacitor CAP_a. the source of Mp1 is connected to the low power source, and the source of Mn1 is grounded. Thus, the number of inverters can be set according to specific requirements.
Continue to refer to FIG. 3, the circuit structure of the voltage conversion circuit 230 is essentially the same as the voltage conversion circuit structure used with a high power source in the prior art shown in FIG. 1, the difference is that the voltage conversion circuit 230 in this embodiment omits the high power source, Specifically, it includes a third PMOS transistor Mpls2, a fourth PMOS transistor Mprs2, a fifth PMOS transistor Mpls1, a sixth PMOS transistor Mprs1, as well as a third NMOS transistor Mnls1 and a fourth NMOS transistor Mnrs1;
Specifically, the source of the third PMOS transistor Mpls2 is connected to the source of the fourth PMOS transistor Mprs2 and connected to the upper plate of capacitor CAP_b, the drain of the third PMOS transistor Mpls2 and the drain of the fourth PMOS transistor Mprs2 are respectively connected to the source of the fifth PMOS transistor and the source of the sixth PMOS transistor, the drains of the fifth PMOS transistor Mpls1 and the sixth PMOS transistor Mprs1 are respectively connected to the drains of the third NMOS transistor Mnls1 and the fourth NMOS transistor Mnrs1, the sources of the third NMOS transistor Mnls1 and the fourth NMOS transistor Mnrs1 are grounded;
the gate of the fifth PMOS transistor Mpls1 is connected to the gate of the third NMOS transistor Mnls1 and connected to the input voltage Vin, the gate of the sixth PMOS transistor Mprs1 is connected to the gate of the fourth NMOS transistor Mnrs1 and connected to the inverse voltage Vinf of the input voltage;
the gate of the fourth PMOS transistor Mprs2 is connected to the drain of the fifth PMOS transistor Mpls1, the gate of the third PMOS transistor Mpls2 is connected to the drain of the sixth PMOS transistor Mprs1 and serves as the output voltage terminal Vout of the voltage conversion circuit.

Specifically, in this embodiment, the body (substrate) of the fifth PMOS transistor Mpls1 is connected to its source, and the body (substrate) of the sixth PMOS transistor Mprs1 is connected to its source.

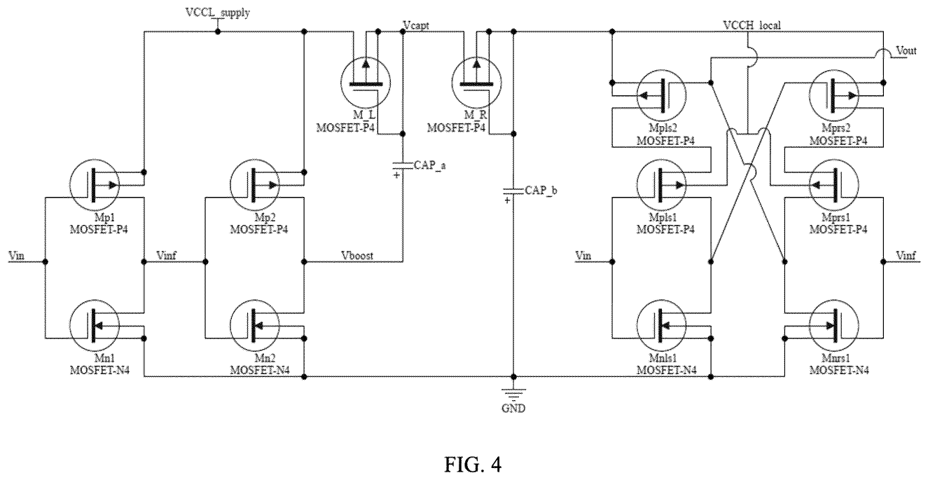

Of course, in other embodiments, as shown in FIG. 4, the body (substrate) of the fifth PMOS transistor Mpls1 can also be connected to the body (substrate) of the sixth PMOS transistor Mprs1, and their connection point can be connected to one end VCCH_local of the voltage conversion circuit. That is, the body of the fifth PMOS transistor Mpls1 and the body of the sixth PMOS transistor Mprs1 can either be connected to the VCCH_local terminal or directly to their respective sources, this application is not limited to these configurations. The following description will use the structure of the level shifting circuit in FIG. 3 as an example for illustration.

Next, in conjunction with FIG. 3, a detailed description of the working principle and operation process of the level shifting circuit based on a low power source in this embodiment will be provided.
First, for the PMOS transistor M_L, since the gate of M_L is connected to Vcapt, current can only flow from VCCL_supply to Vcapt, and the reverse current is zero. For the PMOS transistor M_R, since the gate of M_R is connected to VCCH_local, current can only flow from Vcapt to VCCH_local, and the reverse current is zero;
At the initial operation, since there is no leakage current at VCCH_local, M_R is in the off state; since the source of M_L is connected to VCCL_supply, a small leakage current will charge the upper plate Vcapt of capacitor CAP_a through M_L, making Vcapt equal to VCCL_supply;
Next, when Vboost rises from 0V to VCCL_supply, that is the voltage of the lower plate of capacitor CAP_a rises from 0V to VCCL_supply, since the voltage difference between the two ends of capacitor CAP_a is fixed, therefore the voltage Vcapt on the upper plate of capacitor CAP_a will rise from the initial VCCL_supply to VCCL_supply+VCCL_supply, which is twice the VCCL_supply;
Then, the voltage conversion circuit 230 composed of six MOS transistors (Mpls1, Mpls2, Mnls1, Mprs1, Mprs2, Mnrs1) performs voltage conversion, during the voltage conversion process, the voltage conversion circuit draws a portion of the charge from the boosting capacitor CAP_a and the voltage holding capacitor CAP_b, so VCCH_local (the high level of the output voltage Vout) will be slightly lower than 2 times of VCCL_supply. The function of capacitor CAP_b is to assist CAP_a in making the VCCH_local voltage closer to 2 times of VCCL_supply;
Next, when Vboost decreases from VCCL_supply to 0V, due to the leakage current from VCCL_supply flows through M_L to Vcapt, Vcapt remains at VCCL_supply, when Vboost rises from 0V to VCCL_supply again, Vcapt will being once again be restored to twice VCCL_supply.

It should be noted that during the above process, for capacitor CAP_a, the voltage difference between its two plates is constant. When the voltage of the lower plate rises, the voltage of the upper plate will follow and rise by the same magnitude. When the lower plate rises from 0V to VCCL_supply, the upper plate is at a high-impedance point because M_L cannot leak current from right to left, and the voltage conversion circuit on the right side only consumes a small amount of charge during the voltage conversion period and does not leak current in a steady state. For the capacitor CAP_b, which is connected between VCCH_local and GND, its function is to preserve the charge at the high-impedance point VCCH_local, reducing the charge consumption during the voltage conversion process and preventing the voltage drop at VCCH_local, thereby ensuring that VCCH_local is as close as possible to twice VCCL_supply.

Through the above level shifting process, the voltage conversion circuit 230 achieves continuous variation of the voltage level at the output terminal Vout between 0V and VCCH_local (slightly less than twice VCCL_supply), realizing a high output voltage level of VCCH_local while operating with only a single low power source VCCL_supply. Compared to existing level shifting circuits, this approach eliminates the need for a high voltage source, thereby simplifying the circuit structure.

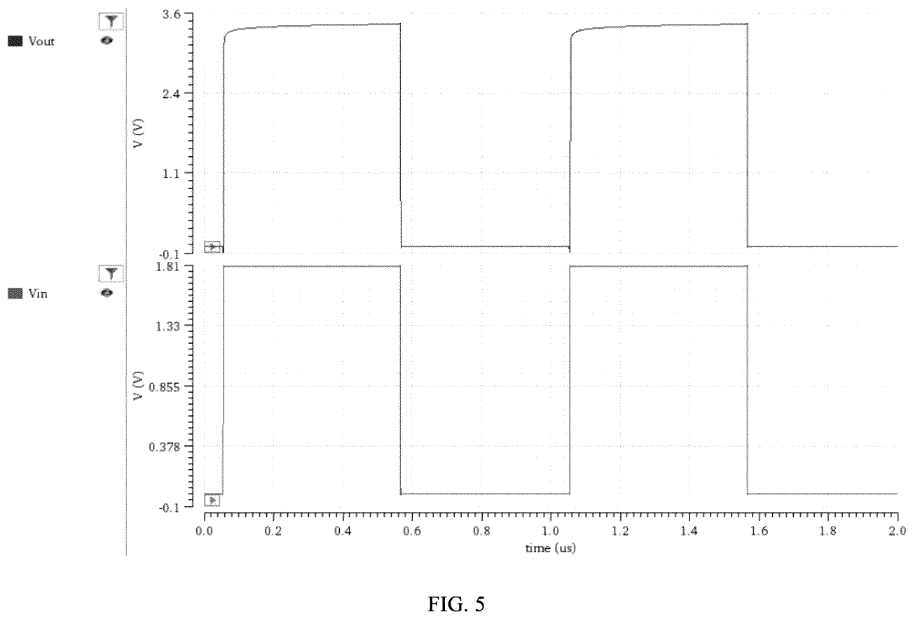

Referring to FIG. 5, FIG. 5 is a schematic diagram of the simulation results of the level shifting circuit based on a low power source as shown in FIG. 3. In FIG. 5, Vin is the input signal from the low power source (VCCL_supply=1.8V), and Vout is the output waveform of the converted high voltage, which is about 3.5V. From the simulation results, it can be seen that the level shifting circuit in FIG. 3 produces a converted high voltage of approximately twice the low power source VCCL_supply. Its technical effect is comparable to that of existing level shifting circuits.

Further attention should be paid to the embodiment illustrated in FIG. 3. The first unidirectional conducting tube 241 can also be an NMOS transistor or diode, and similarly, the second unidirectional conducting tube 242 can also be a unidirectional conducting NMOS transistor or diode. Of course, the first unidirectional conducting tube 241 and the second unidirectional conducting tube 242 can also be a mixture of NMOS, PMOS or diodes.

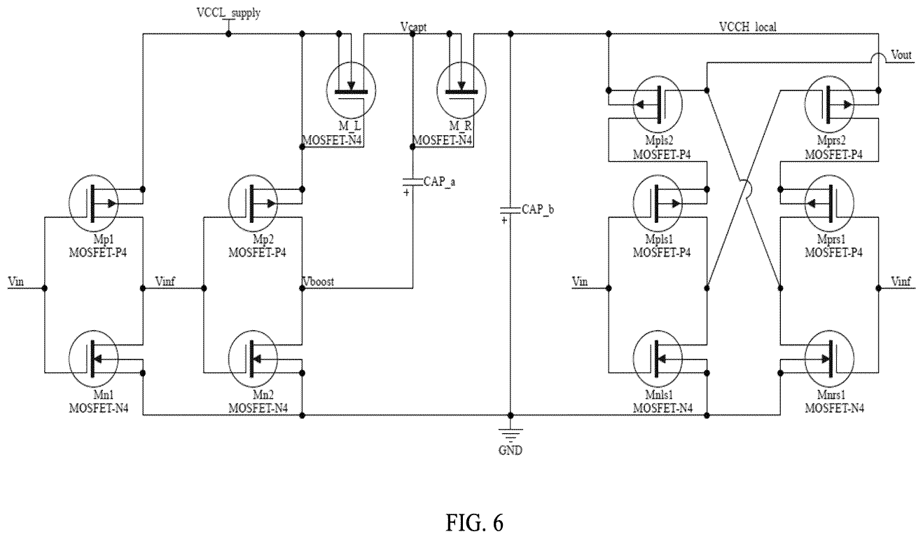

Referring to FIG. 6, which illustrates a schematic diagram of the level shifting circuit based on a low power source according to another embodiment of this application. The operational principle and circuit structure of this embodiment's level shifting circuit are similar to those of the embodiment in FIG. 3. The difference lies in that, in this embodiment, the first unidirectional conducting tube 241 adopts an NMOS transistor M_L, and second unidirectional conducting tube 242 adopts an NMOS transistor M_R. The gate of the first unidirectional conducting tube M_L is connected to its drain and is connected to a low power source VCCL_supply. The source of the first unidirectional conducting tube is connected to the upper plate of the boosting capacitor CAP_a. The gate of the second unidirectional conducting tube M_R is connected to its drain and is connected to the source of the first unidirectional conducting tube M_L. The source of the second unidirectional conducting tube M_R is connected to the VCCH_local of the voltage conversion circuit.

Similarly, during operation, for NMOS transistor M_L, the current flows from VCCL_supply to Vcapt, and the reverse current is zero; for NMOS transistor M_R, the current flows from Vcapt to VCCH_local, and the reverse current is zero. For the circuit structure and operational process not elaborated in this embodiment, reference can be made to the relevant parts in the embodiment of FIG. 3, which are not reiterated here.

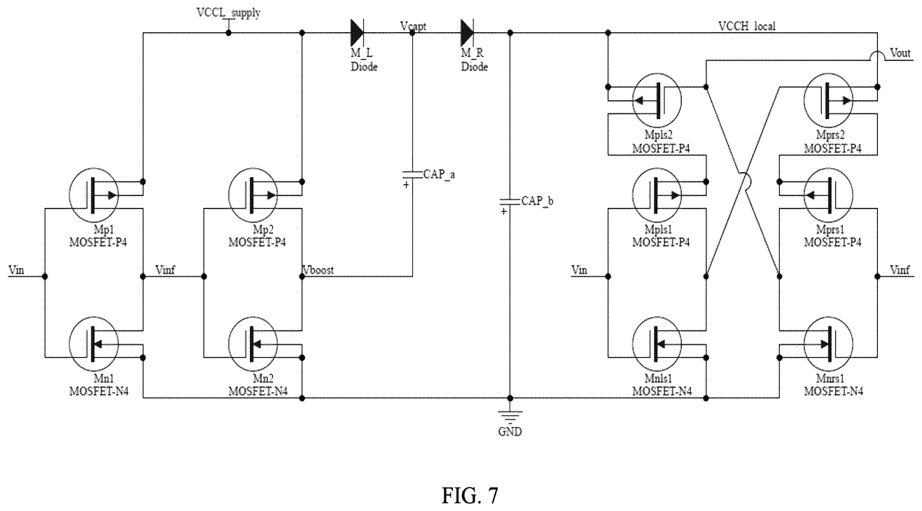

Referring to FIG. 7, which illustrates a schematic diagram of the level shifting circuit based on a low power source according to another embodiment of this application. The operational principle and circuit structure of this embodiment's level shifting circuit are similar to those of the embodiment in FIG. 3. The difference lies in that, in this embodiment, the first unidirectional conducting tube 241 adopts a diode M_L, and the second unidirectional conducting tube 242 adopts a diode M_R. The anode of the first unidirectional conducting tube M_L is connected to the low power source VCCL_supply, and the cathode is connected to Vcapt. The anode of the second unidirectional conducting tube M_R is connected to Vcapt, and the cathode is connected to VCCH_local.

Similarly, during operation, for diode M_L, the current flows from VCCL_supply to Vcapt, and the reverse current is zero; for diode M_R, the current flows from Vcapt to VCCH_local, and the reverse current is zero. For the circuit structure and operational process not elaborated in this embodiment, reference can be made to the relevant parts in the embodiment of FIG. 3, which are not reiterated here.

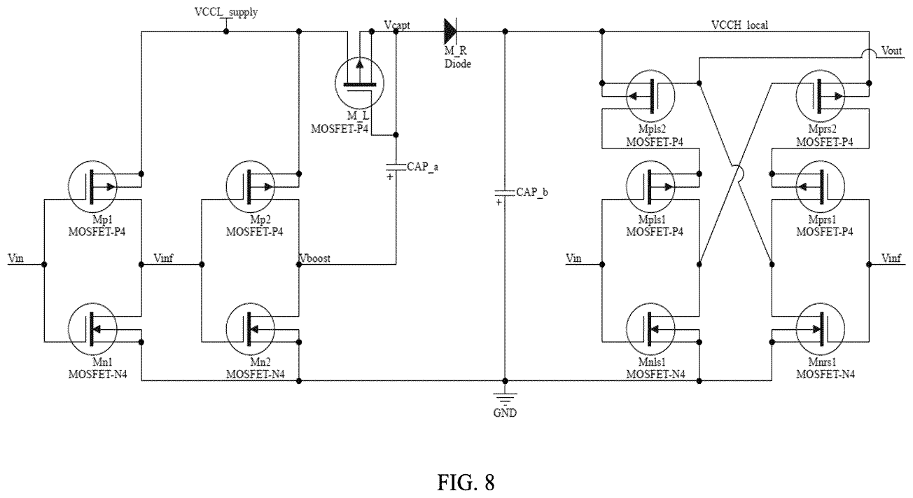

Referring to FIG. 8, which illustrates a schematic diagram of the level shifting circuit based on a low power source according to another embodiment of this application. The operational principle and circuit structure of this embodiment's level shifting circuit are similar to those of the embodiment in FIG. 3. The difference lies in that, in this embodiment, the first unidirectional conducting tube 241 adopts a PMOS transistor M_L, and the second unidirectional conducting tube 242 adopts a diode M_R. The source of the first unidirectional conducting tube M_L is connected to the power source VCCL_supply. The gate of the first unidirectional conducting tube M_L is connected to its drain and is also connected to the upper plate of the capacitor CAP_a. The anode of the second unidirectional conducting tube M_R is connected to the drain of the first unidirectional conducting tube M_L, and the cathode of the second unidirectional conducting tube M_R is connected to VCCH_local of the voltage conversion circuit.

Similarly, during operation, for the PMOS transistor M_L, the current flows from VCCL_supply to Vcapt, and the reverse current is zero; for the diode M_R, the current flows from Vcapt to VCCH_local, and the reverse current is zero. For the circuit structure and operational process not elaborated in this embodiment, reference can be made to the relevant parts in the embodiment of FIG. 3, which are not reiterated here.

An embodiment of the level shifting circuit based on a low power source in this application utilizes a boosting capacitor CAP_a and two unidirectional conducting devices (a combination of PMOS, NMOS, or diodes). This configuration enables the voltage on the upper plate of the boosting capacitor CAP_a to vary between VCCL_supply and VCCH_local (approximately twice the value of VCCL_supply), thus achieving an output voltage of the level shifting circuit that varies between 0V and VCCH_local. In other words, this application achieves a high voltage conversion function with an output voltage twice the value of the low power source using only a single low power source VCCL_supply, thereby addressing the issue in existing circuits that require an additional high power source.

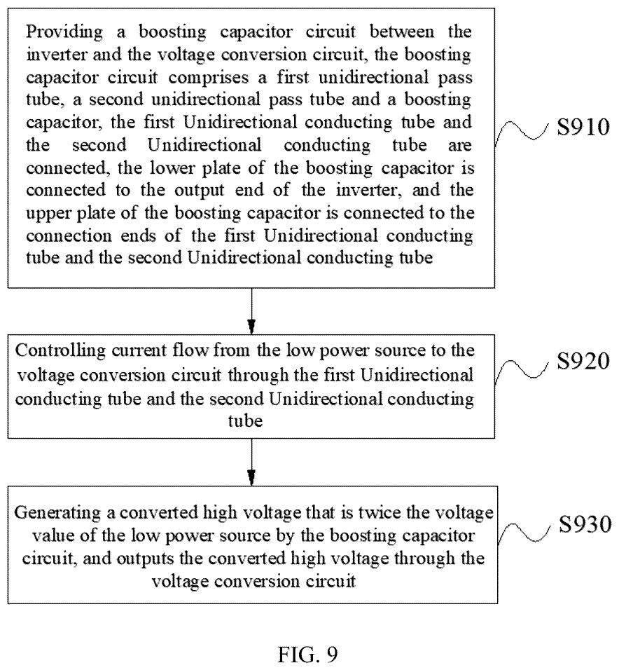

Furthermore, the embodiment of this application also provides a level shifting method based on a low power source, comprising a low power source, an inverter, and a voltage conversion circuit. In some embodiments, as shown in FIG. 9, the method includes the following steps:
S910: providing a boosting capacitor circuit between the inverter and the voltage conversion circuit, the boosting capacitor circuit comprises a first unidirectional pass tube, a second unidirectional pass tube and a boosting capacitor, the first unidirectional conducting tube and the second unidirectional conducting tube are connected, the lower plate of the boosting capacitor is connected to the output end of the inverter, and the upper plate of the boosting capacitor is connected to the connection ends of the first unidirectional conducting tube and the second unidirectional conducting tube;
S920: controlling current flow from the low power source to the voltage conversion circuit through the first unidirectional conducting tube and the second unidirectional conducting tube;
S930: generating a converted high voltage that is twice the voltage value of the low power source by the boosting capacitor circuit, and outputs the converted high voltage through the voltage conversion circuit.

The conversion process not detailed in this embodiment of the level shifting method based on a low power source can be referred to the relevant parts of the level shifting circuit described in the above embodiments, which are not reiterated here.

The above description is merely a preferred embodiment of the present invention and is not intended to limit the invention in any other form. Any person skilled in the art may make modifications or alterations to the disclosed technical content to create equivalent embodiments applicable to other fields. However, any simple modifications, equivalent changes, and adaptations made to the above embodiments based on the technical essence of the present invention, without departing from the content of the technical solutions of the present invention, shall still fall within the protection scope of the technical solutions of the present invention.

1. A level shifting circuit based on low power source, comprising low power source, inverter and voltage conversion circuit, the low power source is connected to the power terminal of the inverter, wherein a boosting capacitor circuit is provided between the inverter and the voltage conversion circuit, the boosting capacitor circuit controls the current flow from the low power source to the voltage conversion circuit, generating a converted high voltage that is twice the voltage value of the low power source, and outputs the converted high voltage through the voltage conversion circuit.

2. The level shifting circuit according to claim 1, wherein the boosting capacitor circuit comprises a first unidirectional conducting tube, a second unidirectional conducting tube and a boosting capacitor, the first unidirectional conducting tube and the second unidirectional conducting tube are connected to control current flow from the low power source to the voltage conversion circuit, the lower plate of the boosting capacitor is connected to the output end of the inverter, and the upper plate of the boosting capacitor is connected to the connection ends of the first unidirectional conducting tube and the second unidirectional conducting tube, and a converted high voltage that is twice the voltage value of the low power source is generated at the connection end.

3. The level shifting circuit according to claim 2, wherein the first unidirectional conducting tube and the second unidirectional conducting tube are PMOS transistors, the source of the first unidirectional conducting tube is connected to the low power source, while the gate and drain of the first unidirectional conducting tube are connected and connected to the upper plate of the boosting capacitor, the source of the second unidirectional conducting tube is connected to the drain of the first unidirectional conducting tube, and the gate and drain of the second unidirectional conducting tube are connected to one end of the voltage conversion circuit.

4. The level shifting circuit according to claim 2, wherein the first unidirectional conducting tube and the second unidirectional conducting tube are NMOS transistors, the gate and drain of the first unidirectional conducting tube are connected and connected to the low power source, the source of the first unidirectional conducting tube is connected to the upper plate of the boosting capacitor, the gate of the second unidirectional conducting tube is connected to the drain and connected to the source of the first unidirectional conducting tube, the source of the second unidirectional conducting tube is connected to one end of the voltage conversion circuit.

5. The level shifting circuit according to claim 2, wherein the boosting capacitor circuit further comprises a voltage holding capacitor, the upper plate of the voltage holding capacitor is connected to one end of the voltage conversion circuit, and the lower plate of the voltage holding capacitor is grounded.

6. The level shifting circuit according to claim 2, wherein the inverter includes a first inverter
and a second inverter;
wherein the first inverter includes a first PMOS transistor and a first NMOS transistor, the gate of the first PMOS transistor and the gate of the first NMOS transistor are connected as the input terminal of the first inverter and connected to the input voltage, the drain of the first PMOS transistor and the drain of the first NMOS transistor are connected as the output terminal of the first inverter, the output terminal of the first inverter is connected to the input terminal of the second inverter, the source of the first PMOS transistor is connected to the low power source, the source of the first NMOS transistor is grounded;
wherein the second inverter includes a second PMOS transistor and a second NMOS transistor, the gate of the second PMOS transistor and the gate of the second NMOS transistor are connected as the input terminal of the second inverter, the drain of the second PMOS transistor and the drain of the second NMOS transistor are connected as the output terminal of the second inverter, the output end of the second inverter is connected to the lower plate of the boosting capacitor, the source of the second PMOS transistor is connected to the low power source, the source of the second NMOS transistor is grounded.

7. The level shifting circuit according to claim 2, wherein the voltage conversion circuit comprises a third PMOS transistor, a fourth PMOS transistor, a fifth PMOS transistor, a sixth PMOS transistor, as well as a third NMOS transistor and a fourth NMOS transistor;
wherein the source of the third PMOS transistor is connected to the source of the fourth PMOS transistor and connected to the output end of the second unidirectional conductor, the drains of the third PMOS transistor and the fourth PMOS transistor are respectively connected to the sources of the fifth PMOS transistor and the sixth PMOS transistor, the drains of the fifth PMOS transistor and the sixth PMOS transistor are respectively connected to the drains of the third NMOS transistor and the fourth NMOS transistor, the sources of the third NMOS transistor and the fourth NMOS transistor are grounded;
wherein the gate of the fifth PMOS transistor is connected to the gate of the third NMOS transistor and connected to the input voltage, the gate of the sixth PMOS transistor is connected to the gate of the fourth NMOS transistor and connected to the inverse voltage of the input voltage;
wherein the gate of the fourth PMOS transistor is connected to the drain of the fifth PMOS transistor, the gate of the third PMOS transistor is connected to the drain of the sixth PMOS transistor and serves as the output voltage terminal of the voltage conversion circuit.

8. The level shifting circuit according to claim 7, wherein the body and source of the fifth PMOS transistor are connected, the body and source of the sixth PMOS transistor are connected.

9. The level shifting circuit according to claim 7, wherein the body of the fifth PMOS transistor is connected to the body of the sixth PMOS transistor and connected to the output end of the second unidirectional conducting tube.

10. A level shifting method based on low power source, comprising low power source, inverter and voltage conversion circuit, the low power source is connected to the power terminal of the inverter, wherein the method comprising:
providing a boosting capacitor circuit between the inverter and the voltage conversion circuit, the boosting capacitor circuit comprises a first unidirectional pass tube, a second unidirectional pass tube and a boosting capacitor, the first unidirectional conducting tube and the second unidirectional conducting tube are connected, the lower plate of the boosting capacitor is connected to the output end of the inverter, and the upper plate of the boosting capacitor is connected to the connection ends of the first unidirectional conducting tube and the second unidirectional conducting tube;
controlling current flow from the low power source to the voltage conversion circuit through the first unidirectional conducting tube and the second unidirectional conducting tube;
generating a converted high voltage that is twice the voltage value of the low power source by the boosting capacitor circuit, and outputs the converted high voltage through the voltage conversion circuit.
